(19) United States
(12) Patent Application Publication
(10) Pub. No.: US 2022/0316059 A1
(43) Pub. Date: Oct. 6, 2022

(54) SUBSTRATE PROCESSING METHOD AND SUBSTRATE PROCESSING APPARATUS

(71) Applicant: Tokyo Electron Limited, Tokyo (JP)

(72) Inventors: Koukichi HIROSHIRO, Kumamoto (JP); Makoto MURAMATSU, Kumamoto (JP); Koji KAGAWA, Kumamoto (JP); Kenji SEKIGUCHI, Nirasaki-shi, Yamanashi (JP)

(21) Appl. No.: 17/628,682

(22) PCT Filed: Jul. 13, 2020
(86) PCT No.: PCT/JP2020/027187

§ 371 Date: Jan. 20, 2022

(30) Foreign Application Priority Data
Jul. 25, 2019 (JP) 2019-137062

(51) Int. Cl. C23C 16/455; C23C 16/458; C23C 16/46

(52) U.S. Cl. CPC C23C 16/45525; C23C 16/4583; C23C 16/46

(57) ABSTRACT

A substrate processing method includes a protective film forming step, an insulating material depositing step, a protective film removing step, and a metal material depositing step. In the protective film forming step, a protective film is formed on a metal film among the metal film and an insulating film exposed on the surface of a substrate, using a film-forming material that is selectively adsorbed onto the metal film. In the insulating material depositing step, after the protective film forming step, an insulating material is deposited on the surface of the insulating film using an atomic layer deposition method. In the protective film removing step, the protective film is removed from the surface of the metal film after the insulating material depositing step. In the metal material depositing step, a metal material is deposited on the metal film after the protective film removing step.

This is a National Phase Application filed under 35 U.S.C. 371 as a national stage of PCT/JP2020/027187, filed Jul. 13, 2020, an application claiming the benefit of Japanese Application No. 2019-137062, filed Jul. 25, 2019, the content of each of which is hereby incorporated by reference in its entirety.

### TECHNICAL FIELD

The present disclosure relates to a substrate processing method and a substrate processing apparatus.

### BACKGROUND

Conventionally, there is known a technique of performing patterning on a substrate such as a semiconductor wafer using an exposure machine.

### PRIOR ART DOCUMENTS

### Patent Documents

Patent Document 1: Japanese Laid-Open Patent Publication No. 2015-156472

The present disclosure provides a technique capable of reducing the number of exposures in a technique of forming a pattern on a substrate.

### SUMMARY

A substrate processing method according to the present disclosure includes a protective film forming step, an insulating material depositing step, a protective film removing step, and a metal material depositing step. In the protective film forming step, a protective film is formed on a metal film among the metal film and an insulating film exposed on the surface of a substrate, using a film-forming material that is selectively adsorbed onto the metal film. In the insulating material depositing step, after the protective film forming step, an insulating material is deposited on the surface of the insulating film using an atomic layer deposition method. In the protective film removing step, the protective film is removed from the surface of the metal film after the insulating material depositing step. In the metal material depositing step, a metal material is deposited on the surface of the metal film after the protective film removing step.

According to the present disclosure, it is possible to reduce the number of exposures in a technique of forming a pattern on a substrate.

### BRIEF DESCRIPTION OF DRAWINGS

FIG. 1 is a block diagram illustrating an example of a configuration of a substrate processing apparatus according to an embodiment.

FIG. 2 is a view illustrating an example of a configuration of a wafer according to an embodiment.

FIG. 3 is a view illustrating experimental results regarding a protective film forming process according to an embodiment.

FIG. 4 is a view illustrating an example of a configuration of a protective film forming part according to an embodiment.

FIG. 5 is a view illustrating an example of a configuration of an insulating film forming part according to an embodiment.

FIG. 6 is a view illustrating an example of a configuration of a protective film removing part according to an embodiment.

FIG. 7 is a view illustrating an example of a configuration of a metal film forming part according to an embodiment.

FIG. 8 is a flowchart illustrating a processing procedure executed by the substrate processing apparatus according to the embodiment.

FIG. 9 is a view illustrating an example of a wafer after the protective film forming process.

FIG. 10 is a view illustrating an example of a wafer after an insulating material depositing process.

FIG. 11 is a view illustrating an example of a wafer after a protective film removing process.

FIG. 12 is a view illustrating an example of a wafer after a metal material depositing process.

FIG. 13 is a view illustrating an example in which an oxide film removing process, the protective film forming process, the insulating material depositing process, the protective film removing process, and the metal material depositing process are repeated.

FIG. 14 is a view illustrating an example of a wafer on which a metal film and an insulating film having a desired film thickness are formed.

### DETAILED DESCRIPTION

Hereinafter, aspects (hereinafter, referred to as “embodiments”) for implementing a substrate processing method and a substrate processing apparatus according to the present disclosure will be described in detail with reference to the accompanying drawings. The substrate processing apparatus and the substrate processing method according to the present disclosure are not limited by these embodiments. It is possible to appropriately combine respective embodiments as long as the processing features thereof do not contradict one another. In each of the following embodiments, the same components will be denoted by the same reference numerals, and redundant descriptions will be omitted.

In the embodiments described below, expressions such as “constant,” “orthogonal,” “perpendicular,” or “parallel” may be used, but these expressions do not have to be strictly “constant,” “orthogonal,” “perpendicular,” or “parallel.” That is, each of the above expressions allows for a deviation in manufacturing accuracy, installation accuracy, or the like.

### <Configuration Example of Substrate Processing Apparatus>

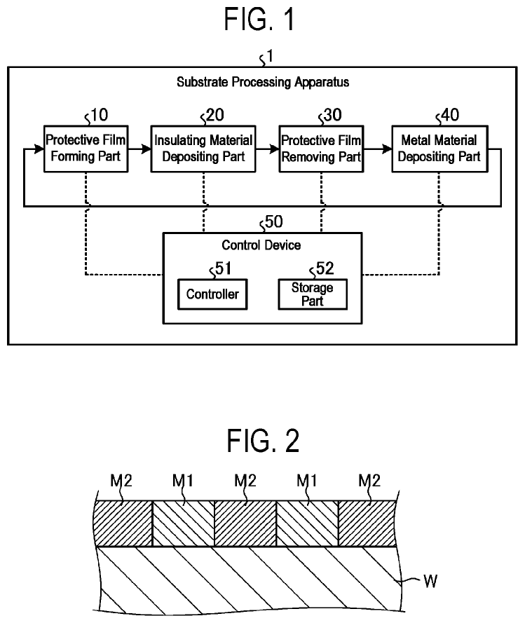

First, a configuration example of the substrate processing apparatus according to the embodiment will be described. FIG. 1 is a block diagram illustrating an example of a configuration of a substrate processing apparatus according to an embodiment. FIG. 2 is a view illustrating an example of a configuration of a wafer according to an embodiment.

As illustrated in FIG. 1, the substrate processing apparatus 1 includes a protective film forming part 10, an insulating material depositing part 20, a protective film removing part 30, a metal material depositing part 40, and a control device 50.

The substrate processing apparatus 1 performs patterning on the wafer W illustrated in FIG. 2 without using an exposure machine.

Specifically, as illustrated in FIG. 2, the wafer W is a silicon wafer, a compound semiconductor wafer, or the like, and a metal film M1 and an insulating film M2 are exposed on a surface thereof. The metal film M1 and the insulating film M2 are alternately formed along the plate surface of the wafer W.

The metal material forming the metal film M1 is any one of osmium, iridium, rhodium, and ruthenium. The metal material forming the metal film M1 may be an alloy containing at least one of osmium, iridium, rhodium, and ruthenium. In addition, the metal material forming the metal film M1 may contain a non-metal material such as silicon in addition to at least one of osmium, iridium, rhodium, and ruthenium. In this case, the proportion of the non-metallic material in the metallic material is preferably 20% or less.

The insulating film M2 is, for example, an interlayer insulating film, and is formed of, for example, a silicon-based insulating film or a metal oxide film-based insulating film. As the silicon-based insulating film, for example, a silicon oxide film, a silicon thermal oxide film, a silicon nitride film, a silicon oxynitride film, or the like may be used. As the metal oxide film, for example, an aluminum oxide film, a hafnium oxide film, a zirconium oxide film, or the like may be used.

The protective film forming part 10 forms a protective film on the surface of the metal film M1 among the metal film M1 and the insulating film M2 exposed on the surface of the wafer W by using a film-forming material that is selectively adsorbed onto the metal film M1.

The film-forming material according to the embodiment is a material containing a sulfur atom. For example, the film-forming material is thiol (R¹—SH), disulfide (R²—S—S—R³), thiocyanate (R⁴—SCN), or the like. In addition, each of R¹ to R⁴ independently represents a substituted or unsubstituted alkyl group. The substituted alkyl group is, for example, a halogen-substituted alkyl group.

The sulfur atom contained in the film-forming material may be bonded to the metal film M1 containing any one of osmium, iridium, rhodium, and ruthenium. As a result, the film-forming material may selectively form a film (hereinafter, referred to as a “protective film”) on the surface of the metal film M1.

The protective film is a monolayer film. The monolayer film is a film in which only one layer of molecules is adsorbed onto the surface of an object. For example, the monolayer film is formed by adsorbing a molecule having a functional group that can be adsorbed to only one position of a molecule or is formed such that one molecule is dissociated and only one side of the dissociated portion or both sides of the dissociated portion are adsorbed. That is, the protective film is a self-assembled monolayer (SAM). In addition, the protective film formed by the film-forming material may be a multilayer film. The multilayer film is a film formed when molecules are laminated and adsorbed, wherein the molecule has, for example, a functional group that can be adsorbed to a plurality of positions of a molecule.

However, when an oxide film, such as a natural oxide film, is formed on the surface of the metal film M1, there is a possibility that film formation by the film-forming material is not properly performed. Therefore, in the protective film forming part 10, the film-forming material is supplied to the surface of the wafer W in a state in which the atmosphere in contact with the surface of the wafer W is maintained in a deoxidized atmosphere. This makes it possible to suitably form a film on the surface of the metal film M1.

In the present disclosure, the “deoxidized atmosphere” is an atmosphere having an oxygen concentration of 50 ppm or less. More preferably, the “deoxidized atmosphere” is an atmosphere having an oxygen concentration of 10 ppm or less.

In the substrate processing apparatus 1 according to an embodiment, the process of supplying the film-forming material to the surface of the wafer W (hereinafter, referred to as a “protective film forming process”) is performed in a state in which the temperature of the film-forming material or the wafer W is raised to a temperature higher than room temperature (e.g., 21 degrees C.). This makes it possible to reduce the time required for the protective film forming process.

In the present specification, the “temperature higher than room temperature” is a temperature of 25 degrees C. or higher. More preferably, the “temperature higher than room temperature” is a temperature of 36 degrees C. or higher.

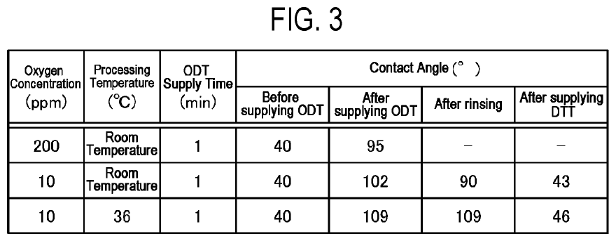

Experimental results regarding these points will be described with reference to FIG. 3. FIG. 3 is a diagram showing the experimental results regarding the protective film forming process according to the embodiment.

The inventors of the present application performed an experiment in which a film was formed on the surface of cobalt by supplying octadecanethiol (ODT) as a film-forming material to a silicon wafer (hereinafter referred to as a “sample”) in which cobalt is exposed on the surface thereof. The ODT was supplied to the sample in a state of being diluted to 0.01 mol/L with isopropyl alcohol (IPA). The ODT supply time was 1 minute.

In addition, before supplying the ODT to the sample, the inventors of the present application performed a process of etching the surface of the cobalt (a natural oxide film) by about 2 nm by supplying an etchant (HCl) to the surface of the sample in order to remove the natural oxide film formed on the surface of the cobalt.

The process of supplying the etchant to the surface of the sample and the process of supplying the ODT to the surface of the sample were performed in a glove box in which the oxygen concentration was adjusted. The inventors of the present application performed the above two processes after adjusting the oxygen concentration in the glove box to 200 ppm or 10 ppm by supplying nitrogen into the glove box. In addition, the inventors of the present application performed the above two processes at room temperature (21 degrees C.), that is, in a state in which the temperature was not raised, and in a state where the temperature was raised to 36 degrees C. The contact angle of the cobalt surface was 40 degrees before supplying the ODT.

As illustrated in FIG. 3, when the oxygen concentration was set to 200 ppm, the contact angle of the cobalt surface after supplying the ODT is 95 degrees, which is considerably smaller than 109 degrees which is the contact angle when the ODT is completely adsorbed onto the surface. In contrast, when the oxygen concentration was set to 10 ppm and when the cobalt surface was processed at room temperature, the contact angle of the cobalt surface after supplying the ODT is 102 degrees, while when the cobalt surface was processed at 36 degrees C., the contact angle of the cobalt surface after supplying the ODT is 109 degrees, so the contact angles were significantly increased compared with that before supplying the ODT. From these results, it can be seen that by supplying ODT under a deoxidized atmosphere, an ODT film is suitably formed on the surface of cobalt in a short period of time. The inventors of the present application conducted a similar experiment at an oxygen concentration of 50 ppm, and have confirmed that good results were obtained as in the case of the oxygen concentration of 10 ppm.

In addition, the inventors of the present application performed a process of supplying a rinsing liquid to the sample after supplying the ODT. As the rinsing liquid, deionized water (DIW) and IPA were used. As illustrated in FIG. 3, when the ODT was supplied at an oxygen concentration of 10 ppm and at room temperature, the contact angle of the cobalt surface after supplying the rinsing liquid was 90 degrees. In contrast, when the ODT was supplied at an oxygen concentration of 10 ppm and at 36 degrees C., the contact angle of the cobalt surface after supplying the rinsing liquid was 109 degrees, which was the same as the contact angle before rinsing. From this result, it can be seen that by supplying the ODT at 36 degrees C., an ODT film is suitably formed on the cobalt surface compared with the case in which the ODT is supplied at room temperature. The inventors of the present application conducted a similar experiment at a processing temperature of 25 degrees C., and have confirmed that good results were obtained as in the case of a processing temperature of 36 degrees C.

The inventors of the present application conducted an experiment of removing a film formed on a cobalt surface by supplying a reducing agent to the sample after supplying the rinsing liquid. As the reducing agent, dithiothreitol (DTT) was used. As a result, as illustrated in FIG. 3, when the DTT was supplied at room temperature, the contact angle of the cobalt surface was decreased to 43 degrees and when the DTT was supplied at 36 degrees C., the contact angle of the cobalt surface was decreased to 46 degrees. From these results, it can be seen that the film formed on the cobalt surface is satisfactorily removed by using the DTT.

As is clear from the above experimental results, it is desirable to perform the protective film forming process in a deoxidized atmosphere and under a heated environment. In addition, it is desirable to use a reducing agent such as DTT for removing the film formed on the surface of the metal film M1. As a mechanism for removing the film by the reducing agent, for example, it may be considered that the film is removed from the surface of the metal film M1 since an exchange reaction occurs between the film formed on the surface of the metal film M1 and the reducing agent. Examples of the reducing agent include 2-mercaptoethanol, 2-mercaptoethylamine hydrochloride, TCEP-HCl (tris (2-carboxyethyl) phosphine hydrochloride), and the like, in addition to the DTT.

The insulating material depositing part 20 performs an insulating material depositing process for depositing an insulating material on the surface of the insulating film M2 on the wafer W on which a protective film has been formed on the surface of the metal film M1 by the protective film forming part 10. The insulating material depositing part 20 is a film forming apparatus, and deposits an insulating material on the surface of the insulating film M2 by using an atomic layer deposition (ALD) method. In such an insulating material depositing process, the surface of the metal film M1 is covered with a protective film. Therefore, when using the substrate processing apparatus 1, it is possible to prevent the insulating material from being deposited on the surface of the metal film M1.

The protective film removing part 30 performs a protective film removing process for removing the protective film from the surface of the metal film M1 on the wafer W on which the insulating material has been deposited on the surface of the insulating film M2 by the insulating material depositing part 20. For example, the protective film removing part 30 may remove the protective film from the surface of the metal film M1 by supplying a reducing agent, such as DTT, 2-mercaptoethanol, 2-mercaptoethylamine hydrochloride, or TCEP-HCl described above to the surface of the wafer W.

The metal material depositing part 40 performs a metal material depositing process for depositing a metal material on the surface of the metal film M1 on the wafer W after the protective film has been removed from the surface of the metal film M1. For example, the metal material depositing part 40 is a plating apparatus and deposits a metal material on the surface of the metal film M1 by using an electroplating method or an electroless plating method.

The control device 50 is a device that controls the operation of the substrate processing apparatus 1. The control device 50 is, for example, a computer, and includes a controller 51 and a storage part 52. The storage part 52 stores a program that controls various processes such as an etching process. The controller 51 controls the operations of the protective film forming part 10, the insulating material depositing part 20, the protective film removing part 30, and the metal material depositing part 40 by reading and executing the program stored in the storage part 52. The controller 51 is, for example, a central processing unit (CPU), a microprocessor unit (MPU), or the like, and the storage part 52 is, for example, a read only memory (ROM), a random access memory (RAM), or the like.

In addition, such a program may be stored in a computer-readable storage medium, and may be installed in the storage part 52 of the control device 50 from the storage medium. The computer-readable storage medium includes, for example, a hard disk (HD), a flexible disk (FD), a compact disk (CD), a magneto-optical disk (MO), and a memory card.

The substrate processing apparatus 1 repeatedly performs the processes by the protective film forming part 10, the insulating material depositing part 20, the protective film removing part 30, and the metal material depositing part 40 described above to bottom up the metal film M1 and the insulating film M2. As a result, the substrate processing apparatus 1 is capable of forming a pattern including the metal film M1 and the insulating film M2 having a desired film thickness on the wafer W without using an exposure machine.

Here, as described above, osmium, iridium, rhodium, and ruthenium, which are candidates for the metal material forming the metal film M1, are less likely to undergo electromigration than, for example, cobalt. Therefore, when the metal film M1 is formed using these metals, the step of forming a barrier metal for preventing the diffusion of atoms around the metal film M1 may be omitted. Therefore, in the substrate processing apparatus 1, a step of bottoming up the metal film M1 and the insulating film M2 by repeating the processes by the protective film forming part 10, the insulating material depositing part 20, the protective film removing part 30, and the metal material depositing part 40 can be easily performed.

The candidates for the metal material forming the metal film M1 are not limited to osmium, iridium, rhodium, and ruthenium. Specifically, the metal material forming the metal film M1 may be any one of gold, silver, copper, iron, cobalt, nickel, zinc, rhodium, ruthenium, palladium, platinum, osmium, and iridium. Like osmium, iridium, rhodium, and ruthenium, gold, silver, copper, iron, cobalt, nickel, zinc, palladium, and platinum also have the property of binding to sulfur atoms. Therefore, by forming the metal film M1 using any one of gold, silver, copper, iron, cobalt, nickel, zinc, palladium, and platinum, it is possible to form a protective film on the surface of the metal film M1. In addition, the metal material forming the metal film M1 may be an alloy containing at least one of gold, silver, copper, iron, cobalt, nickel, zinc, rhodium, ruthenium, palladium, platinum, osmium, and iridium. The metal material forming the metal film M1 may include, for example, a non-metal material, such as silicon, in addition to at least one of gold, silver, copper, iron, cobalt, nickel, zinc, rhodium, ruthenium, palladium, platinum, osmium, and iridium. In this case, the proportion of the non-metallic material in the metal material is preferably 20% or less.

Although not illustrated here, the substrate processing apparatus 1 may include a carry-in/out station on which a carrier capable of accommodating a plurality of wafers W is placed. Furthermore, the substrate processing apparatus 1 may include a transfer part that sequentially transfers wafers W carried in via the carry-in/out station to the protective film forming part 10, the insulating material depositing part 20, the protective film removing part 30, and the metal material depositing part 40.

### <Configuration Example of Protective Film Forming Part>

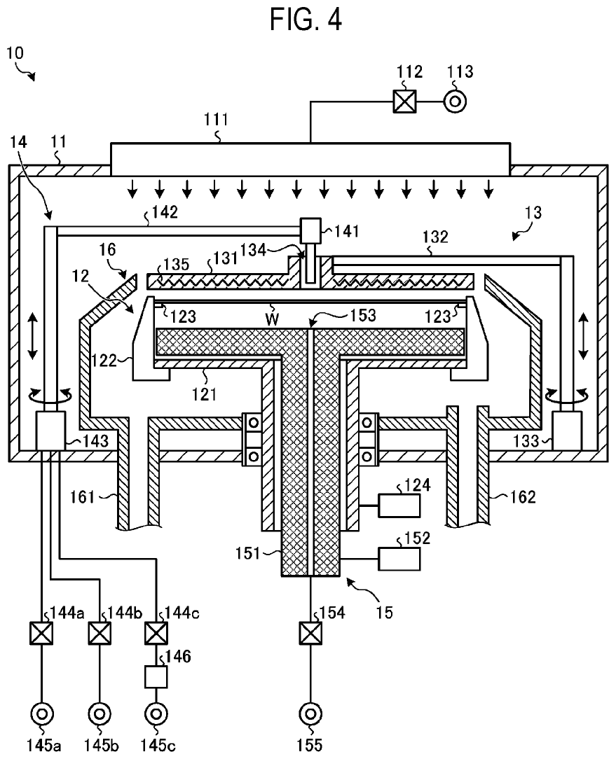

Next, a configuration example of the protective film forming part 10 will be described with reference to FIG. 4. FIG. 4 is a view illustrating an example of a configuration of the protective film forming part 10 according to an embodiment.

As illustrated in FIG. 4, the protective film forming part 10 includes a chamber 11, a substrate holding mechanism 12, a deoxidized atmosphere maintaining part 13, a processing fluid supply part 14, a lower supply part 15, and a recovery cup 16.

The chamber 11 accommodates the substrate holding mechanism 12, the deoxidized atmosphere maintaining part 13, the processing fluid supply part 14, the lower supply part 15, and the recovery cup 16. A ceiling of the chamber 11 is provided with a fan filter unit (FFU) 111. The FFU 111 forms a downflow within the chamber 11. Specifically, the FFU 111 is connected to the downflow gas source 113 via a valve 112. The FFU 111 ejects the downflow gas (e.g., nitrogen or dry air) supplied from the downflow gas source 113 into the chamber 11.

The substrate holding mechanism 12 includes a main body 121 through which an under plate 151 of the lower supply part 15, which will be described later, is inserted, and a holding member 122 provided in the main body 121 and holding a wafer W in a state of being spaced apart from the under plate 151. The holding member 122 includes a plurality of support pins 123 that support the rear surface of a wafer W, wherein the wafer W is held horizontally by making the support pins 123 support the rear surface of the wafer W. The wafer W is supported by the support pins 123 in a state in which the surface on which a metal film M1 and an insulating film M2 are formed faces upward.

The substrate holding mechanism 12 includes a driver 124 that rotates the main part 121 around a vertical axis. The substrate holding mechanism 12 may rotate the wafer W held by the holding member 122 around a vertical axis by rotating the main body 121 using the driver 124.

The substrate holding mechanism 12 is not limited to the type that supports the wafer W from the bottom side as described above, but may be a type that holds the wafer W from the lateral side or may be a type that suctions and holds the wafer W from the bottom side like a vacuum chuck.

The deoxidized atmosphere maintaining part 13 includes a top plate 131, an arm 132 that horizontally supports the top plate 131, and a driver 133 that rotates and moves up and down the arm 132.

The top plate 131 is formed in a size that covers the surface of the wafer W. An opening 134 through which the nozzle 141 included in a processing fluid supply part 14 is inserted is provided in the central portion of the top plate 131. A processing fluid such as a film-forming material is supplied from the opening 134 to the central portion of the wafer W. The top plate 131 includes a heater 135.

The deoxidized atmosphere maintaining part 13 may change the distance between the top plate 131 and the wafer W by moving up and down the arm 132 using the driver 133. Specifically, the deoxidized atmosphere maintaining part 13 moves the top plate 131 between a processing position at which the top plate 131 is close to the surface of the wafer W and covers the top side of the wafer W and a retracted position at which the top plate 131 is separated from the surface of the wafer W and opens the top side of the wafer W.

The processing fluid supply part 14 includes a nozzle 141, an arm 142 that horizontally supports the nozzle 141, and a driver 143 that rotates and moves up and down the arm 142.

The nozzle 141 is connected to an oxide film removing liquid source 145a via a flow regulator 144a. The oxide film removing liquid supplied from the oxide film removing liquid source 145a is an etchant capable of removing an oxide film such as a natural oxide film formed on the metal film M1. As such an etchant, for example, dilute hydrochloric acid or the like is used.

In addition, the nozzle 141 is connected to the rinsing liquid source 145b via the flow regulator 144b. The rinsing liquid supplied from the rinsing liquid source 145b is, for example, DIW or the like.

The nozzle 141 is connected to a protective film forming liquid source 145c via the flow regulator 144c and the heater 146. The protective film forming liquid supplied from the protective film forming liquid source 145c is, for example, a solution obtained by diluting a film-forming material with an organic solvent such as IPA. As the film-forming material, for example, thiol, disulfide, thiocyanate, and the like are used. The protective film forming liquid supplied from the protective film forming liquid source 145c is ejected from the nozzle 141 in a state of being heated to a desired temperature, specifically, a temperature of 25 degrees C. or higher by the heater 146.

Oxygen may be dissolved in the oxide film removing liquid, the rinsing liquid, the organic solvent, and the protective film forming liquid. Here, from the viewpoint of suppressing the oxidation of the surface of the metal film M1, the oxygen concentration in the oxide film removing liquid, the rinsing liquid, the organic solvent, and the protective film forming liquid is preferably low. Therefore, the protective film forming part 10 uses a deoxidized oxide film removing liquid, a deoxidized rinsing liquid, a deoxidized organic solvent, and a deoxidized protective film forming liquid. This makes it possible to reliably suppress oxidation of the surface of the metal film M1. The protective film forming part 10 may include a deoxidizing part that reduces the oxygen concentration in the oxide film removing liquid, the rinsing liquid, the organic solvent, and the protective film forming liquid by bubbling using, for example, an inert gas such as nitrogen.

The flow regulators 144a to 144c include an opening/closing valve, a flow control valve, a flow meter, and the like.

Here, an example in which the protective film forming part 10 includes a single nozzle 141 is illustrated, but the substrate processing apparatus 1 may include a plurality of nozzles and may be configured to eject an oxide film removing liquid, the protective film forming liquid, and the like from separate nozzles.

The lower supply part 15 includes an under plate 151 inserted through the main body 121 of the substrate holding mechanism 12 and disposed below the wafer W, and a driver 152 configured to raise and lower the under plate 151.

The under plate 151 is a member formed in a size that covers the rear surface of the wafer W. Inside the under plate 151, a flow path 153 penetrating the under plate 151 vertically is formed. A heating fluid source 155 is connected to the flow path 153 via a flow regulator 154. The heating fluid supplied from the heating fluid source 155 is used to heat the wafer W. As the heating fluid, for example, an inert gas, such as nitrogen, is used. The heating fluid may be a heated liquid.

The lower supply part 15 supplies the heating fluid supplied from the heating fluid source 155 to the rear surface of the wafer W by ejecting the heating fluid from the flow path 153 in the under plate 151. Thereby, the wafer W may be heated to a desired temperature, specifically, a temperature of 25 degrees C. or higher.

The recovery cup 16 is disposed to surround the substrate holding mechanism 12, and collects the processing liquid scattered from the wafer W by the rotation of the main body 121 and the holding member 122 of the substrate holding mechanism 12. A drainage port 161 is formed in the bottom portion of the recovery cup 16, and the processing liquid collected by the recovery cup 16 is ejected from the drainage port 161 to the outside of the substrate processing apparatus 1. An exhaust port 162 configured to discharge the downflow gas supplied from the FFU 111 to the outside of the substrate processing apparatus 1 is formed in the bottom portion of the recovery cup 16.

### <Configuration Example of Insulating Film Forming Part>

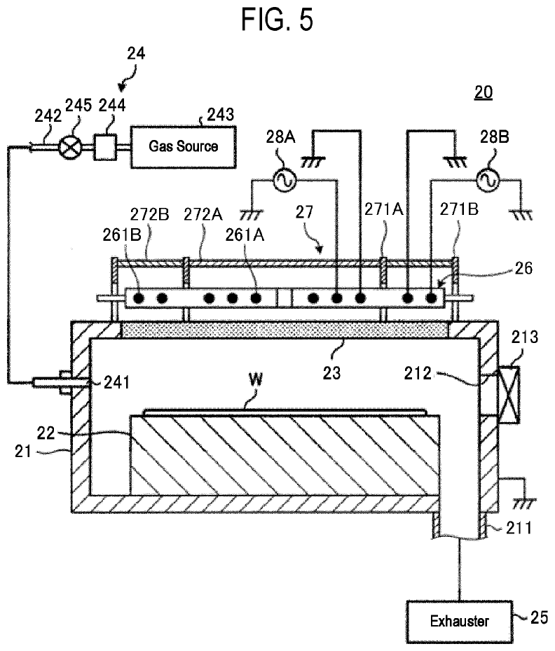

Next, a configuration example of the insulating material depositing part 20 will be described with reference to FIG. 5. FIG. 5 is a view illustrating an example of the configuration of the insulating material depositing part 20 according to an embodiment.

As illustrated in FIG. 5, the insulating material depositing part 20 as a film forming apparatus includes a processing chamber (a chamber) 21 formed in a tubular shape (e.g., a cylindrical shape) made of a metal (e.g., aluminum).

On the bottom portion of the processing chamber 21, a stage 22 configured to place thereon a wafer W is provided. The stage 22 is formed of aluminum or the like into a substantially columnar shape (e.g., a cylindrical columnar shape). Although not illustrated, the stage 22 may be provided with various functions as needed, such as an electrostatic chuck configured to attract and hold the wafer W by an electrostatic force, a temperature regulation mechanism, such as a heater or a coolant flow path, and the like.

A plate-shaped dielectric body 23 made of, for example, quartz glass, ceramic, or the like is provided on the ceiling of the processing chamber 21 to face the stage 22. Specifically, the plate-shaped dielectric body 23 is formed in, for example, a disk shape, and is hermetically installed to close the opening formed in the ceiling of the processing chamber 21.

The processing chamber 21 is provided with a gas supply part 24 configured to supply a processing gas or the like for processing the wafer W. A gas introduction port 241 is formed in the side wall of the processing chamber 21, and a gas source 243 is connected to the gas introduction port 241 via a gas supply pipe 242. A flow controller configured to control the flow rate of the processing gas, for example, a mass flow controller 244 and an opening/closing valve 245, is interposed in the middle of the gas supply pipe 242. The processing gas from the gas source 243 is controlled to a predetermined flow rate by the mass flow controller 244 and is supplied into the processing chamber 21 from the gas introduction port 241.

Although the gas supply part 24 is represented as a gas line of a single system in FIG. 5 in order to simplify the description, the gas supply part 24 is not limited to the case in which a processing gas of a single gas species is supplied, and a plurality of gas species may be supplied as processing gases. In this case, a plurality of gas sources may be provided to configure gas lines of multiple systems, and a mass flow controller may be provided in each gas line. For example, a raw material gas containing a constituent element of an insulating material to be formed, a reaction gas to react with the raw material gas, a purge gas, and the like may be individually supplied.

An exhauster 25 configured to exhaust the atmosphere in the processing chamber 21 is connected to the bottom portion of the processing chamber 21 via an exhaust pipe 211. The exhauster 25 includes, for example, a vacuum pump so that the interior of the processing chamber 21 can be depressurized to a predetermined pressure. A wafer carry-in/out port 212 is formed in the side wall of the processing chamber 21, and a gate valve 213 is provided in the wafer carry-in/out port 212.

On the ceiling of the processing chamber 21, a plane-shaped radio frequency antenna 26 and a shield member 27 covering the radio frequency antenna 26 are disposed on the top side surface (the outside surface) of the plate-shaped dielectric body 23. The radio frequency antenna 26 generally includes an inner antenna element 261A disposed in the central portion of the plate-shaped dielectric body 23 and an outer antenna element 261B disposed to surround the outer periphery of the inner antenna element 261A. Each of the antenna elements 261A and 261B is formed in a spiral coil shape made of a conductor such as copper, aluminum, or stainless steel.

The shield member 27 includes a cylindrical inner shield wall 271A provided between the respective antenna elements 261A and 261B to surround the inner antenna element 261A, and a cylindrical outer shield wall 271B provided to surround the outer antenna element 261B. As a result, the top side surface of the plate-shaped dielectric body 23 is divided into an inner central portion (a central zone) of the inner shield wall 271A and a peripheral edge portion (a peripheral zone) between the respective shield walls 271A and 271B.

A disk-shaped inner shield plate 272A is provided on the inner antenna element 261A to close the opening in the inner shield wall 271A. On the outer antenna element 261B, a donut plate-shaped outer shield plate 272B is provided to close the opening between the respective shield walls 271A and 271B.

Radio frequency power supplies 28A and 28B are separately connected to the antenna elements 261A and 261B, respectively. As a result, radio frequency waves having the same frequency or different frequencies may be applied to each of the antenna elements 261A and 261B. For example, when radio frequency waves having a predetermined frequency (e.g., 40 MHz) are supplied from the radio frequency power supply 28A to the inner antenna element 261A with a predetermined power, an induced magnetic field is formed in the processing chamber 21. The formed induced magnetic field excites the processing gas introduced into the processing chamber 21, and a donut-shaped plasma is generated in the central portion on the wafer W.

In addition, when radio frequency waves having a predetermined frequency (e.g., 60 MHz) are supplied from the radio frequency power supply 28B to the outer antenna element 261B with a predetermined power, an induced magnetic field is formed in the processing chamber 21. The formed induced magnetic field excites the processing gas introduced into the processing chamber 21 to generate another donut-shaped plasma in the peripheral edge portion on the wafer W.

In a state in which these plasmas are generated, a film forming process on the wafer W (in the present embodiment, deposition of an insulating material using an atomic layer deposition method) is executed. The radio frequency waves output from the radio frequency power supplies 28A and 28B are not limited to the frequencies described above. For example, high frequency waves having various frequencies, such as 13.56 MHz, 27 MHz, 40 MHz, and 60 MHz, may be supplied. However, it is necessary to adjust the electrical length of each antenna element 261A or 261B depending on the radio frequency waves output from the radio frequency power supplies 28A and 28B. The generation of plasma is not essential depending on the type of an insulating material to be formed. When plasma generation is not required, the configuration of the radio frequency antenna 26 or the like may be omitted.

### <Configuration Example of Protective Film Removing Part>

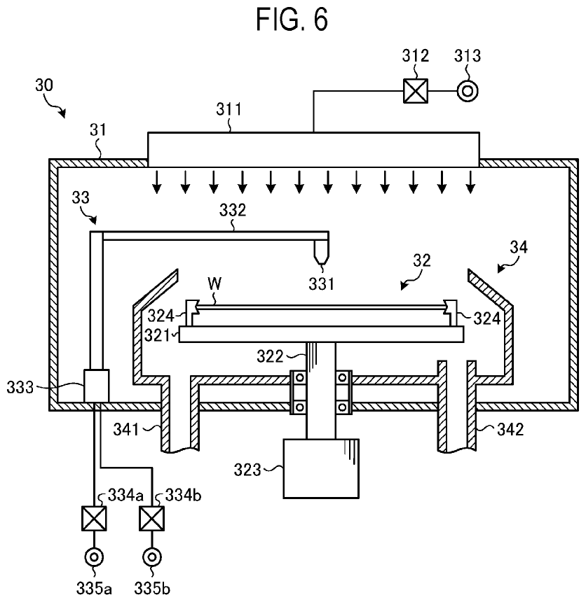

Next, a configuration example of the protective film removing part 30 will be described with reference to FIG. 6. FIG. 6 is a view illustrating an example of the configuration of the protective film removing part 30 according to an embodiment.

As illustrated in FIG. 6, the protective film removing part 30 includes a chamber 31, a substrate holding mechanism 32, a liquid supply part 33, and a recovery cup 34.

The chamber 31 accommodates the substrate holding mechanism 32, the liquid supply part 33, and the recovery cup 34. The ceiling of the chamber 31 is provided with an FFU 311. The FFU 311 forms a downflow within the chamber 31.

The FFU 311 is connected to the downflow gas source 313 via a valve 312. The FFU 311 ejects the downflow gas (e.g., dry air) supplied from the downflow gas source 313 into the chamber 31.

The substrate holding mechanism 32 includes a rotation holding part 321, a support column 322, and a driver 323. The rotation holding part 321 is provided substantially in the center of the chamber 31. A holding member 324 configured to hold a wafer W from the side surface is provided on the top surface of the rotation holding part 321. The wafer W is horizontally held by the holding member 324 in a state of being slightly spaced apart from the top surface of the rotation holding part 321.

The support column 322 is a member extending in the vertical direction, wherein the base end thereof is rotatably supported by the driver 323 and the tip end thereof horizontally supports the rotation holding part 321. The driver 323 rotates the support column 322 around a vertical axis.

The substrate holding mechanism 32 rotates the rotation holding part 321 supported by the support column 322 by rotating the support column 322 using the driver 323, whereby the wafer W held by the rotation holding part 321 is rotated. The rotation holding part 321 is not limited to the type that holds the wafer W from the side surface as described above, and may be a type that suctions and holds the wafer W from the bottom side, such as a vacuum chuck.

The liquid supply part 33 supplies various processing liquids to the wafer W held by the substrate holding mechanism 32. The liquid supply part 33 includes a nozzle 331, an arm 332 configured to horizontally support the nozzle 331, and a rotation lifting mechanism 333 that rotates and moves up and down the arm 332.

The nozzle 331 is connected to a reducing agent source 335a via a flow regulator 334a. As described above, the reducing agent supplied from the reducing agent source 335a is a reducing agent capable of removing a film formed on the surface of a metal film M1. As such a reducing agent, DTT, 2-mercaptoethanol, 2-mercaptoethylamine hydrochloride, TCEP-HCl, or the like is used. In addition, the nozzle 331 is connected to a rinsing liquid source 335b via a flow regulator 334b. The rinsing liquid supplied from the rinsing liquid source 335b is, for example, DIW.

The recovery cup 34 is disposed to surround the rotation holding part 321 and collects the processing liquid scattered from the wafer W due to the rotation of the rotation holding part 321. A drainage port 341 is formed in the bottom portion of the recovery cup 34, and the processing liquid collected by the recovery cup 34 is discharged from the drainage port 341 to the outside of the protective film removing part 30. In addition, an exhaust port 342 is formed in the bottom portion of the recovery cup 34 to discharge the downflow gas supplied from the FFU 311 to the outside of the protective film removing part 30.

In the present embodiment, an example in which the protective film forming part 10 and the protective film removing part 30 are separately provided is illustrated, but the protective film forming part 10 may also be provided with the function of the protective film removing part 30. For example, the reducing agent source 335a may be connected to the nozzle 141 of the processing fluid supply part 14 included in the protective film forming part 10 via the flow regulator 334a. As a result, since it is possible to perform the protective film removing process in the protective film forming part 10, the protective film removing part 30 may be omitted.

### <Constituent Example of Metal Material Depositing Part>

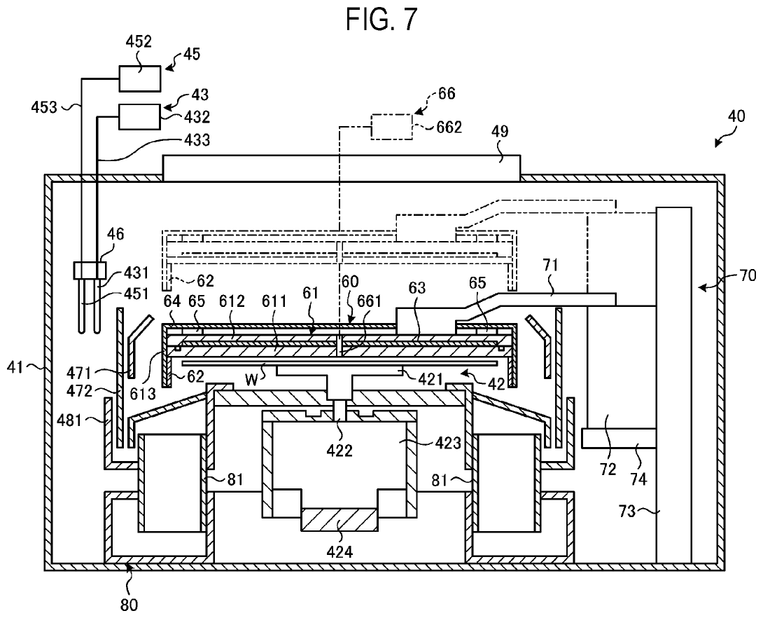

Next, a configuration example of the metal material depositing part 40 will be described with reference to FIG. 7. FIG. 7 is a view illustrating an example of the configuration of the metal material depositing part 40 according to an embodiment.

As illustrated in FIG. 7, the metal material depositing part 40 as a plating apparatus is configured to perform a liquid process including an electroless plating process. The metal material depositing part 40 includes a chamber 41, a holding part 42 disposed in the chamber 41 and configured to horizontally hold a wafer W, and a plating liquid supply part 43 configured to supply a plating liquid to the surface (the top surface) of the wafer W held by the holding part 42.

In the present embodiment, the holding part 42 includes a chuck member 421 configured to vacuum-suction the bottom surface (the rear surface) of the wafer W. The chuck member 421 is a so-called vacuum chuck type.

A rotation motor 423 is connected to the holding part 42 via a rotation shaft 422. When the rotation motor 423 is driven, the holding part 42 rotates together with the wafer W. The rotation motor 423 is supported by a base 424 fixed to the chamber 41. In addition, a heating source, such as a heater, is not provided inside the holding part 42.

The plating liquid supply part 43 includes a plating liquid nozzle 431 configured to eject a plating liquid to the wafer W held by the holding part 42, and a plating liquid source 432 configured to supply the plating liquid to the plating liquid nozzle 431. The plating liquid source 432 is configured to supply a plating liquid heated or temperature-controlled to a predetermined temperature to the plating liquid nozzle 431 via a plating liquid pipe 433. The temperature at the time of ejecting the plating liquid from the plating liquid nozzle 431 is, for example, 55 degrees C. or higher and 75 degrees C. or lower, and more preferably 60 degrees C. or higher and 70 degrees C. or lower. The plating liquid nozzle 431 may be configured to be movable by being held by the nozzle arm 46.

The plating liquid is, for example, a plating liquid for autocatalytic (reduction type) electroless plating. The plating liquid contains, for example, metal ions and a reducing agent. The metal ions contained in the plating liquid are, for example, gold ions, silver ions, copper ions, iron ions, cobalt ions, nickel ions, zinc ions, rhodium ions, ruthenium ions, palladium ions, platinum ions, osmium ions, iridium ions or the like. The reducing agent contained in the plating liquid is, for example, hypophosphorous acid, dimethylamine borane, glyoxylic acid, or the like.

The metal material depositing part 40 further includes a rinsing liquid supply part 45 configured to supply a rinsing liquid to the surface of the wafer W held by the holding part 42. The rinsing liquid supply part 45 includes a rinsing liquid nozzle 451 configured to eject the rinsing liquid to the wafer W held by the holding part 42, and a rinsing liquid source 452 configured to supply the rinsing liquid to the rinsing liquid nozzle 451. The rinsing liquid nozzle 451 is configured to be movable together with the plating liquid nozzle 431 by being held by the nozzle arm 46. In addition, the rinsing liquid source 452 is configured to supply the rinsing liquid to the rinsing liquid nozzle 451 via a rinsing liquid pipe 453. As the rinsing liquid, for example, DIW or the like may be used. A nozzle moving mechanism (not illustrated) is connected to the nozzle arm 46.

A cup 471 is provided around the holding part 42. The cup 471 is formed in a ring shape when viewed from the top side, and when the wafer W rotates, the cup 471 receives the processing liquid scattered from the wafer W and guides the processing liquid to a drain duct 481. An atmosphere blocking cover 472 is provided on the outer peripheral side of the cup 471 to prevent the atmosphere around the wafer W from diffusing into the chamber 41. The atmosphere blocking cover 472 is formed in a cylindrical shape to extend in the vertical direction, and the upper end thereof is open. A lid 60, which will be described later, can be inserted into the atmosphere blocking cover 472 from the top side.

In the present embodiment, the wafer W held by the holding part 42 is covered with the lid 60. The lid 60 includes a ceiling 61 and a side wall 62 extending downward from the ceiling 61.

The ceiling 61 includes a first ceiling plate 611 and a second ceiling plate 612 provided on the first ceiling plate 611. A heater 63 is interposed between the first ceiling plate 611 and the second ceiling plate 612. The first ceiling plate 611 and the second ceiling plate 612 are configured to seal the heater 63 such that the heater 63 does not come into contact with a processing liquid such as a plating liquid. More specifically, a seal ring 613 is provided on the outer peripheral side of the heater 63, and the heater 63 is sealed by the seal ring 613.

A lid moving mechanism 70 is connected to the lid 60 via a lid arm 71. The lid moving mechanism 70 moves the lid 60 in the horizontal direction and the vertical direction. More specifically, the lid moving mechanism 70 includes a rotation motor 72 configured to move the lid 60 in the horizontal direction, and a cylinder 73 configured to move the lid 60 in the vertical direction. The rotation motor 72 is mounted on a support plate 74 provided to be movable in the vertical direction with respect to the cylinder 73.

The rotation motor 72 of the lid moving mechanism 70 moves the lid 60 between an upper position disposed above the wafer W held by the holding part 42 and a retracted position retracted from the upper position. Of these positions, the upper position is a position at which the lid 60 faces the wafer W held by the holding part 42 with a relatively large interval therebetween and the lid 60 overlaps the wafer W when viewed from the top side. The retracted position is a position at which the lid 60 does not overlap the wafer W within the chamber 41 when viewed from the top side. When the lid 60 is positioned at the retracted position, the moving nozzle arm 46 is prevented from interfering with the lid 60. The rotation axis of the rotation motor 72 extends in the vertical direction, and the lid 60 is configured to rotationally move in the horizontal direction between the upper position and the retracted position.

The cylinder 73 of the lid moving mechanism 70 moves the lid 60 in the vertical direction to adjust the distance between the wafer W to which the plating liquid is supplied and the first ceiling plate 611 of the ceiling 61. More specifically, the cylinder 73 positions the lid 60 at a lower position (the position illustrated by solid lines in FIG. 7) and an upper position (the position illustrated by alternate long and two short dashes lines in FIG. 7).

The present embodiment is configured such that when the heater 63 is driven and the lid 60 is positioned at the lower position described above, the plating liquid on the holding part 42 or the wafer W is heated.

An inert gas (e.g., nitrogen gas) is supplied to the interior of the lid 60 by an inert gas supply part 66. The inert gas supply part 66 includes a gas nozzle 661 configured to eject the inert gas to the interior of the lid 60, and an inert gas source 662 configured to supply the inert gas to the gas nozzle 661. The gas nozzle 661 among these is provided on the ceiling 61 of the lid 60, and ejects the inert gas toward the wafer W in a state in which the lid 60 covers the wafer W.

The ceiling 61 and the side wall 62 of the lid 60 are covered with the lid cover 64. The lid cover 64 is placed on the second ceiling plate 612 of the lid 60 via a support 65. That is, a plurality of supports 65 protruding upward from the top surface of the second ceiling plate 612 are provided on the second ceiling plate 612, and the lid cover 64 is placed on the supports 65. The lid cover 64 is configured to be movable in the horizontal direction and the vertical direction together with the lid 60.

In the upper portion of the chamber 41, an FFU 49 configured to supply clean air (gas) around the lid 60 is provided. The FFU 49 supplies air into the chamber 41 (particularly into the atmosphere blocking cover 472), and the supplied air flows toward the exhaust pipe 81. A downflow of the air flowing downward is formed around the lid 60, and the gas vaporized from a processing liquid, such as a plating liquid, flows toward an exhaust pipe 81 by this downflow. In this way, the gas vaporized from the processing liquid is prevented from rising and diffusing into the chamber 41. The gas supplied from FFU 49 is discharged by an exhaust mechanism 80.

### <Specific Operation of Substrate Processing Apparatus>

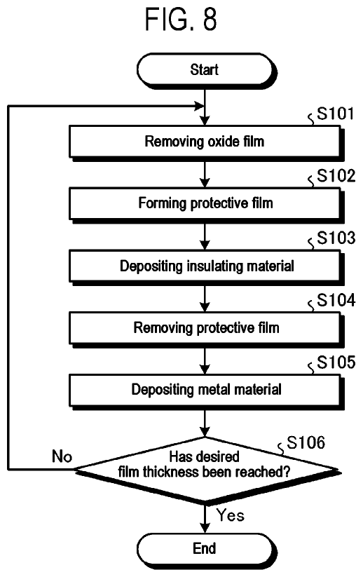

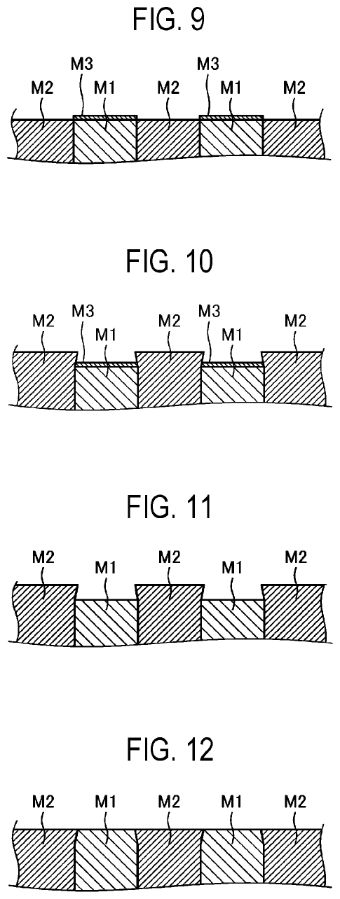

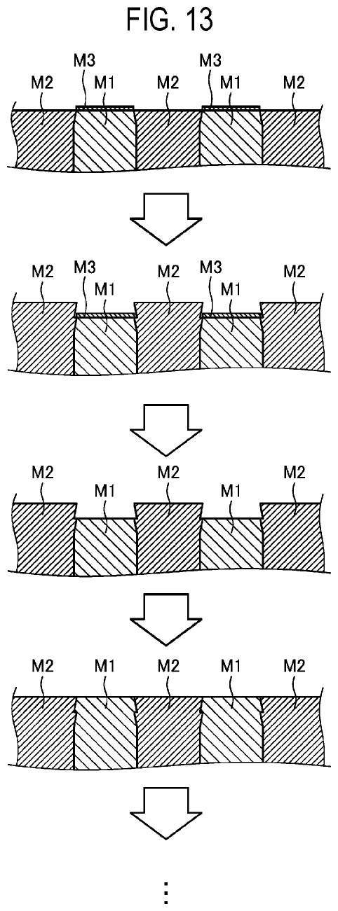

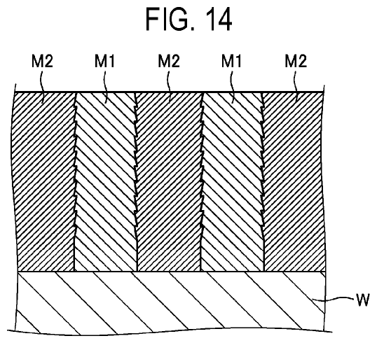

The operation of the substrate processing apparatus 1 will be described with reference to FIGS. 8 to 14. FIG. 8 is a flowchart illustrating a procedure of processing performed by the substrate processing apparatus 1 according to an embodiment. FIG. 9 is a view illustrating an example of a wafer W after the protective film forming process, and FIG. 10 is a view illustrating an example of the wafer W after the insulating material depositing process. FIG. 11 is a view illustrating an example of the wafer W after the protective film removing process, and FIG. 12 is a view illustrating an example of the wafer W after the metal material depositing process. FIG. 13 is a view illustrating an example in which the oxide film removing process, the protective film forming process, the insulating material depositing process, the protective film removing process, and the metal material depositing process are repeated, and FIG. 14 is a view illustrating an example of the wafer W on which the metal film M1 and an insulating film M2 having a desired film thickness are formed. Each apparatus included in the substrate processing apparatus 1 performs each processing procedure illustrated in FIG. 8 under the control of the controller 51.

As illustrated in FIG. 8, in the substrate processing apparatus 1, first, the oxide film removing process is performed by the protective film forming part 10 (step S101).

Specifically, a wafer W carried into the chamber 11 of the protective film forming part 10 by a transfer part (not illustrated) is held by the substrate holding mechanism 12. The wafer W is held by the holding member 122 in a state in which the pattern forming surface illustrated in FIG. 2 faces upward. Thereafter, the main body 121 and the holding member 122 are rotated by the driver 124. As a result, the wafer W is rotated together with the holding member 122.

Subsequently, the top plate 131 of the deoxidized atmosphere maintaining part 13 is disposed at the processing position. In addition, the nozzle 141 of the processing fluid supply part 14 is inserted through the opening 134 of the top plate 131. Then, when the valve of the flow regulator 144a is opened for a predetermined time, an oxide film removing liquid is supplied from the nozzle 141 to the surface of the wafer W. The oxide film removing liquid supplied to the surface of the wafer W spreads over the entire surface of the wafer W due to the rotation of the wafer W. As a result, the space between the wafer W and the top plate 131 is filled with the oxide film removing liquid. By supplying the oxide film removing liquid to the surface of the wafer W, an oxide film formed on the surface of the metal film M1 can be removed. This makes it possible to suitably form a film on the surface of the metal film M1 in the subsequent protective film forming process.

Subsequently, the valve of the flow regulator 144b is opened for a predetermined time, whereby a rinsing liquid is supplied from the nozzle 141 to the surface of the wafer W. The rinsing liquid supplied to the surface of the wafer W spreads over the entire surface of the wafer W due to the rotation of the wafer W. As a result, the oxide film removing liquid on the wafer W is removed from the wafer W by the rinsing liquid, and the space between the wafer W and the top plate 131 is filled with the rinsing liquid.

Subsequently, in the substrate processing apparatus 1, a protective film forming process is performed by the protective film forming part 10 (step S102). In the protective film forming process, the valve of the flow regulator 144c is opened for a predetermined time, so that a heated protective film forming liquid is supplied from the nozzle 141 to the surface of the wafer W. The protective film forming liquid supplied to the surface of the wafer W spreads over the entire surface of the wafer W due to the rotation of the wafer W. As a result, the space between the wafer W and the top plate 131 is filled with the protective film forming liquid. Then, by supplying the protective film forming liquid to the surface of the wafer W, a protective film M3 is selectively formed on the surface of the metal film M1 (see FIG. 9). Thereafter, the top plate 131 of the deoxidized atmosphere maintaining part 13 moves from above the wafer W to the retracted position.

As described above, in the substrate processing apparatus 1 according to the embodiment, since the space between the wafer W and the top plate 131 is filled with the oxide film removing liquid, the rinsing liquid, or the protective film forming liquid until the protective film forming process is completed, the atmosphere in contact with the surface of the wafer W is maintained in a deoxidized atmosphere. As a result, since the formation of an oxide film on the surface of the metal film M1 is suppressed, the protective film M3 can be suitably formed on the surface of the metal film M1 in the protective film forming process.

Since the protective film forming liquid is supplied to the wafer W in a state of being heated by the heater 146, the protective film M3 can be more suitably formed on the surface of the metal film M1 in a short period of time compared with the case in which the protective film forming liquid is not heated. In addition, the substrate processing apparatus 1 may heat the protective film forming liquid on the wafer W using the heater 135 provided in the top plate 131. In addition, the substrate processing apparatus 1 may also heat the wafer W by supplying a heating fluid from the lower supply part 15. As a result, since the processing temperature during the protective film forming process can be maintained at a desired temperature, the formation of the protective film M3 on the metal film M1 can be more suitably performed. Here, an example in which the top plate 131 includes the heater 135 has been described, but it suffices if the top plate 131 is capable of adjusting the processing temperature during the protective film forming process, and the top plate 131 may be configured to include a temperature controller including a function of cooling in addition to a function of heating.

In addition, it is possible to suppress the liquid remaining on the lower surface of the top plate 131 from dropping and adhering to the surface of the wafer W by moving the top plate 131 of the deoxidized atmosphere maintaining part 13 from the top side of the wafer W to the retracted position after the protective film forming process. Without being limited to this, the substrate processing apparatus 1 may include, for example, a saucer configured to receive the liquid falling from the top plate 131 and a driver configured to move the saucer. In this case, after the top plate 131 is raised, the saucer is moved to the space between the top plate 131 and the wafer W. This makes it possible to suppress the liquid falling from the top plate 131 from adhering to the surface of the wafer W.

In the protective film forming process, the substrate processing apparatus 1 continues to supply the protective film forming liquid from the processing fluid supply part 14, whereby the protective film forming liquid remaining in the space between the top plate 131 and the surface of the wafer W may be discharged. When a liquid remains in the space between the top plate 131 and the surface of the wafer W for a long period of time, oxygen dissolves in the remaining liquid, and the dissolved oxygen may reach the surface of the metal film M1 by diffusion or the like and may oxidize the surface of the metal film M1. In contrast, by continuously supplying the protective film forming liquid to discharge the liquid remaining on the surface of the wafer W, it is possible to suppress oxygen from reaching the surface of the metal film M1.

Before the protective film forming process, the substrate processing apparatus 1 may perform a substitution process in which the rinsing liquid on the wafer W is replaced with an organic solvent such as IPA, which has a high affinity with the protective film forming liquid. In this case, the nozzle 141 may be connected to the organic solvent source via the flow regulator. In addition, the substrate processing apparatus 1 may be configured such that a heated rinsing liquid is supplied to the rear surface of the wafer W from the lower supply part 15 in the protective film forming process. As a result, it is possible to suppress the wraparound of the protective film forming liquid to the rear surface of the wafer W.

Subsequently, the valve of the flow regulator 144b is opened for a predetermined time, so that a rinsing liquid is supplied from the nozzle 141 to the surface of the wafer W. The rinsing liquid supplied to the surface of the wafer W spreads over the entire surface of the wafer W due to the rotation of the wafer W. As a result, the protective film forming liquid on the wafer W is removed from the wafer W by the rinsing liquid. Thereafter, the rotation of the wafer W by the driver 152 is accelerated. As a result, the rinsing liquid remaining on the wafer W is centrifugally scattered from the wafer W, whereby the wafer W is dried.

Subsequently, the wafer W after the protective film forming process is transferred to the insulating material depositing part 20 by a transfer part (not illustrated). Then, an insulating material depositing process is performed in the insulating material depositing part 20 (step S103).

In the insulating material depositing process, the insulating material depositing part 20 deposits an insulating material on the surface of the insulating film M2 using an atomic layer deposition method in which a raw material gas containing a constituent element of the insulating material and a reaction gas are alternately supplied (see FIG. 10). Here, when the insulating material is deposited on the surface of the insulating film M2, the insulating film M2 extends in the height direction and also spreads in the horizontal direction. Therefore, when a large amount of the insulating material is deposited on the surface of the insulating film M2 in one process, adjacent insulating films M2 may stick to each other and cover the metal film M1. Therefore, the thickness of the insulating material deposited in one process is preferably several nm to ten plus several nm, and preferably several tens of nm at most.

Subsequently, the wafer W after the insulating material depositing process is transferred to the protective film removing part 30 by a transfer part (not illustrated). The protective film removing part 30 holds the carried-in wafer W horizontally using the rotation holding part 321. Then, the protective film removing process is performed in the protective film removing part 30 (step S104).

In the protective film removing process, the protective film removing part 30 rotates the wafer W using the driver 323. Thereafter, a reducing agent is supplied from the nozzle 331 to the surface of the wafer W by opening the valve of the flow regulator 334a for a predetermined time. The reducing agent supplied to the surface of the wafer W spreads over the entire surface of the wafer W due to the rotation of the wafer W. As a result, the protective film M3 formed on the surface of the metal film M1 is removed, and the surface of the metal film M1 is exposed (see FIG. 11).

Subsequently, the valve of the flow regulator 334b is opened for a predetermined time, whereby the rinsing liquid is supplied from the nozzle 331 to the surface of the wafer W. The rinsing liquid supplied to the surface of the wafer W spreads over the entire surface of the wafer W due to the rotation of the wafer W. As a result, the reducing agent on the wafer W is removed from the wafer W by the rinsing liquid. Thereafter, the rotation of the wafer W by the driver 323 is accelerated. As a result, the rinsing liquid remaining on the wafer W is centrifugally scattered from the wafer W, whereby the wafer W is dried.

Subsequently, the wafer W after the protective film removing process is transferred to the metal material depositing part 40 by a transfer part (not illustrated). Then, the metal material depositing process is performed in the metal material depositing part 40 (step S105). In the metal material depositing part 40, a metal material is deposited on the surface of the metal film M1 through a plating process (see FIG. 12). Here, when the metal material is excessively deposited on the surface of the metal film M1, there is a possibility that adjacent metal films M1 come into contact with each other and cause a short circuit. Therefore, the thickness of the metal material deposited in one metal material depositing process is about the same as the thickness of the insulating material deposited in one insulating material depositing process, that is, preferably several nm to ten plus several nm, at most about several tens of nm.

Here, the metal material is deposited through a plating process using the metal material depositing part 40, but the metal material depositing process may be performed using an atomic layer deposition method. In this case, since the metal material depositing process can be performed using the insulating material depositing part 20 in the substrate processing apparatus 1, the metal material depositing part 40 as the plating apparatus may be omitted.

Subsequently, the substrate processing apparatus 1 determines whether or not the metal film M1 and the insulating film M2 have reached a desired film thickness (step S106). When the metal film M1 and the insulating film M2 have not reached the desired film thickness (step S106, “No”), the respective processes of steps S101 to S105 are repeated until the metal film M1 and the insulating film M2 reach the desired film thickness (see FIG. 13). Then, when the metal film M1 and the insulating film M2 have reached the desired film thickness (step S106, “Yes”), the substrate processing apparatus 1 terminates the series of substrate processes for one wafer W.

In this way, the substrate processing apparatus 1 repeats the oxide film removing process, the protective film forming process, the insulating material depositing process, the protective film removing process, and the metal material depositing process. As a result, a pattern including the metal film M1 and the insulating film M2 having a desired film thickness can be formed on the surface of the wafer W by the substrate processing apparatus 1 (see FIG. 14).

### Modification

The protective film removing part 30 may remove the protective film M3 from the surface of the metal film M1 by irradiating the wafer W with ultraviolet (UV) after the insulating material depositing process. In this case, the protective film removing part 30 may include, for example, a UV irradiation part that irradiates substantially the entire surface of the wafer W with UV.

In the above-described embodiment, the deoxidized atmosphere is locally formed using the deoxidized atmosphere maintaining part 13. Without being limited thereto, the protective film forming part 10 may form a deoxidized atmosphere in the entire chamber 11 by supplying an inert gas, such as nitrogen, from, for example, the FFU 111.

In the above-described embodiment, descriptions have been made of an example in which the metal material forming the metal film M1 contains at least one of gold, silver, copper, iron, cobalt, nickel, zinc, rhodium, ruthenium, palladium, platinum, osmium, and iridium. Without being limited thereto, the metal material may be, for example, tungsten. Sulfur atoms do not adhere to the surface of tungsten. Therefore, when the metal material contains tungsten, it is preferable to supply a material having a Si—N bond (a direct bond of silicon atom and nitrogen atom) to the surface of the substrate as a film-forming material. For example, when trimethylsilyldimethylamine (TMSDMA) is used as the film-forming material, dimethylamine (—N(CH₃)₂) binds to tungsten contained in the metal material, thereby forming a film on the surface of the metal material.

As described above, the substrate processing method according to an embodiment includes a step of forming a protective film (e.g., the protective film forming process), a step of depositing an insulating material (e.g., the insulating material depositing process), a step of removing the protective film (e.g., the protective film removing process), and a step of depositing a metal material (e.g., the metal material depositing process). In the protective film forming step, by using a film-forming material that is selectively adsorbed onto a metal film among the metal film (e.g., the metal film M1) and an insulating film (e.g., the insulating film M2) exposed to the surface of a substrate (e.g., the wafer W), a protective film (e.g., the protective film M3) is formed on the surface of the metal film. In the insulating material depositing step, after the protective film forming step, an insulating material is deposited on the surface of the insulating film using an atomic layer deposition method. In the protective film removing step, the protective film is removed from the surface of the metal film after the insulating material depositing step. In the metal material depositing step, the metal material is deposited on the surface of the metal film after the protective film removing step.

Therefore, with the substrate processing method according to the embodiment, it is possible to reduce the number of exposures in the technique of forming a pattern on a substrate. In addition, by reducing the number of exposures, it is possible to suppress the occurrence of misalignment that may occur when an exposure machine is used. Therefore, with the substrate processing method according to the embodiment, it is possible to form a pattern on a substrate with high accuracy.

The substrate processing method according to the embodiment may further include a step of repeating the protective film forming step, the insulating material depositing step, the protective film removing step, and the metal material depositing step. By repeating these steps, a metal film and an insulating film having a desired film thickness can be formed. In addition, since the deposition of the metal film and the deposition of the insulating film are not performed at one time, it is possible to suppress problems such as covering the metal film with adjacent insulating films sticking to each other and a short circuit caused by the adjacent metal films sticking to each other.

The metal material may contain at least one of gold, silver, copper, iron, cobalt, nickel, zinc, rhodium, ruthenium, palladium, platinum, osmium, and iridium. In this case, the film-forming material may contain a sulfur atom. As a result, a protective film can be suitably formed on the surface of a metal film containing at least one of gold, silver, copper, iron, cobalt, nickel, zinc, rhodium, ruthenium, palladium, platinum, osmium, and iridium.

The metal material may contain at least one of osmium, iridium, rhodium, and ruthenium. Osmium, iridium, rhodium, and ruthenium are less likely to undergo electromigration than, for example, cobalt. Therefore, when forming a metal film using these metals, a step of forming a barrier metal for preventing diffusion of atoms around the metal film may be omitted. Therefore, according to the substrate processing method according to the embodiment, the step of bottoming up the metal film and the insulating film can be easily performed.

The metal material may be a material containing tungsten. In this case, the film-forming material may be a liquid or gas containing a molecule having a Si—N bond. Thereby, the protective film can be suitably formed on the surface of the metal film containing tungsten.

The substrate processing method according to the embodiment may further include a step of maintaining an atmosphere in contact with the surface of the metal film in a deoxidized atmosphere. In this case, the protective film forming step may be performed in a state in which the atmosphere is maintained in the deoxidized atmosphere. As a result, since the formation of an oxide film on the surface of the metal material is suppressed, the inhibition of the formation of the protective film on the metal film caused by the oxide film can be suppressed in the protective film forming step.

The substrate processing method according to the embodiment may further include a step of removing the oxide film from the surface of the metal film before the protective film forming step. By removing the oxide film such as the natural oxide film from the surface of the metal film in this way, the protective film can be suitably formed on the surface of the metal film in the protective film forming step.

In addition, the substrate processing apparatus (e.g., the substrate processing apparatus 1) according to the embodiment includes a protective film forming part (e.g., the protective film forming part 10), an insulating material depositing part (e.g., the insulating material depositing part 20), a protective film removing part (e.g., the protective film removing part 30), and a metal material depositing part (e.g., the metal material depositing part 40). The protective film forming part forms a protective film on the metal film using a film-forming material that is selectively adsorbed onto the metal film among the metal film and an insulating film exposed on the surface of the substrate. The insulating material depositing part deposits an insulating material on the surface of the insulating film using an atomic layer deposition method. The protective film removing part removes the protective film from the surface of the metal film. The metal material depositing part deposits a metal material on the surface of the metal film.

Therefore, with the substrate processing apparatus according to the embodiment, it is possible to reduce the number of exposures in the technique of forming a pattern on the substrate. In addition, by reducing the number of exposures, it is possible to suppress the occurrence of misalignment that may occur when an exposure machine is used. Therefore, with the substrate processing apparatus according to the embodiment, it is possible to form a pattern on a substrate with high accuracy.

It should be understood that the embodiments disclosed herein are exemplary in all respects and are not restrictive. Indeed, the above-described embodiments can be implemented in various forms. The embodiments described above may be omitted, replaced, or modified in various forms without departing from the scope and spirit of the appended claims.

### EXPLANATION OF REFERENCE NUMERALS

W: wafer, M1: metal film, M2: insulating film, M3: protective film, 1: substrate processing apparatus, 10: protective film forming part, 20: insulating material depositing part, 30: protective film removing part, 40: metal material depositing part, 50: control device, 51: controller, 52: storage part

1-8. (canceled)

9. A substrate processing method comprising:
forming a protective film on a metal film among the metal film and an insulating film exposed on a surface of a substrate, using a film-forming material that is selectively adsorbed onto the metal film;
depositing an insulating material on a surface of the insulating film using an atomic layer deposition method after the forming the protective film;
removing the protective film from the surface of the metal film after the depositing the insulating material; and
depositing a metal material on the surface of the metal film after the removing the protective film.

10. The substrate processing method of claim 9, further comprising:
repeating the forming the protective film, the depositing the insulating material, the removing the protective film, and the depositing the metal material.

11. The substrate processing method of claim 10, wherein the metal material includes tungsten, and
the film-forming material is a liquid or gas containing a molecule having a Si—N bond.

12. The substrate-processing method of claim 11, further comprising:
maintaining an atmosphere in contact with the surface of the metal film in a deoxidized atmosphere,
wherein the forming the protective film is performed in a state in which the deoxidized atmosphere is maintained.

13. The substrate processing method of claim 12, further comprising:
removing an oxide film from the surface of the metal film prior to the forming the protective film.

14. The substrate processing method of claim 9, wherein the metal material includes at least one of gold, silver, copper, iron, cobalt, nickel, zinc, rhodium, ruthenium, palladium, platinum, osmium, and iridium, and
the film-forming material contains a sulfur atom.

15. The substrate processing method of claim 14, wherein the metal material includes at least one of osmium, iridium, rhodium, and ruthenium.

16. The substrate-processing method of claim 9, further comprising:
maintaining an atmosphere in contact with the surface of the metal film in a deoxidized atmosphere,
wherein the forming the protective film is performed in a state in which the deoxidized atmosphere is maintained.

17. The substrate processing method of claim 9, further comprising:
removing an oxide film from the surface of the metal film prior to the forming the protective film.

18. A substrate processing apparatus comprising;
a protective film forming part configured to form a protective film on a metal film among the metal film and an insulating film exposed on a surface of a substrate, using a film-forming material that is selectively adsorbed onto the metal film;
an insulating material depositing part configured to deposit an insulating material on a surface of the insulating film using an atomic layer deposition method;
a protective film removing part configured to remove the protective film from the surface of the metal film; and
a metal material depositing part configured to deposit a metal material on the surface of the metal film.
